(19) United States
(12) Patent Application Publication
(10) Pub. No.: US 2009/0069172 A1
(43) Pub. Date: Mar. 12, 2009

(54) Novel Platinum-Ruthenium Based Catalysts for Direct Methanol Fuel Cell

(75) Inventors: Mina Touma Farag, Cupertino, CA (US); Yi-Qun Li, Danville, CA (US)

Correspondence Address: FLIESLER MEYER LLP, 650 CALIFORNIA STREET, 14TH FLOOR, SAN FRANCISCO, CA, 94108, US

(73) Assignee: INTEMATIX CORPORATION, Fremont, CA (US)

(21) Appl. No.: 12/167,093

(22) Filed: Jul. 2, 2008

Related U.S. Application Data
(60) Provisional application No. 60/962,265, filed on Jul. 27, 2007.
(60) Provisional application No. 60/958,272, filed on Jul. 2, 2007.

(51) Int. Cl. H01M 4/88; B01J 23/648; B01J 23/75; B01J 23/72; C23C 14/46; B01J 23/656; B01J 23/755

(52) U.S. Cl. 502/101; 502/312; 502/313; 502/318; 502/324; 502/315; 204/192.11

(57) ABSTRACT

Embodiments of the present invention are directed to ternary and/or quaternary catalyst alloys for a direct methanol fuel cell (DMFC). The catalyst has the composition (Pt₁₋ₓRuₓ)_{y}M′_{z}M″_{1-y-z}, where M′ is selected from the group consisting of W, Mo, Nb, and Ta; M″ is selected from the group consisting of V, Co, Ni, Mn, and Cu; x ranges from about 0 to about 1; y ranges from about 0.01 to about 0.99; and y+z is about equal to 1. The catalyst may be deposited onto a porous carrier, and the deposition method may include ion-beam sputtering. The onset voltages of the present compositions are lower than that of conventional Pt—Ru binary systems by approximately 0.355 volts, and thus provide enhanced catalytic activity.

### REFERENCE TO RELATED APPLICATIONS

The present application claims priority to U.S. Pat. Application Ser. No. 60/958,272, filed Jul. 2, 2007, by Farag et al. and titled “Novel Platinum-Ruthenium Based Catalysts for Direct Methanol Fuel Cells,” and to U.S. Pat. Application Ser. No. 60/962,265, filed Jul. 27, 2007, by Farag et al. and also titled “Novel Platinum-Ruthenium Based Catalysts for Direct Methanol Fuel Cells.” Application Nos. 60/958,272 and 60/962,265 are hereby incorporated by reference in their entirety.

### FIELD OF THE INVENTION

Embodiments of the present invention are directed in general to direct methanol fuel cells (DMFCs). More specifically, the present embodiments are directed to quaternary metallic anode catalysts for DMFCs based on platinum (Pt)-ruthenium (Ru) alloys.

### BACKGROUND OF THE INVENTION

There has been a decade of effort developing effective catalysts which can produce protons first from hydrogen, ultimately from methanol, to the anode of a direct methanol fuel cell (DMFC) based on polymer electrolytes. Poisoning of catalysts and stability issues associated with the chemical resistance of metal catalysts in harsh environment of DMFC operating conditions are two major barriers to overcome. To the present inventors' knowledge, the only functional catalysts for a DMFC anode today is a PtRu alloy, which shows decent catalytic efficiency, and good stability chemical and physical stability. However, the commercially available PtRu catalysts for DMFC applications are not sufficient for most of the portable electronic applications where the size of the fuel cell is a challenge.

What is needed in the art are more efficient and stable catalyst systems for reducing the size of a DMFC device. An 100% increase in catalyst efficiency is a minimum target for such commercial applications as laptop computers, PDAs, Games and other portable electronics.

### SUMMARY OF THE INVENTION

In the present invention a comprehensive combinatorial search of new catalysts compositions was performed. A carbon nanotube (CNT) integrated carbon fiber based diffusion layer (for example Toray GDS™), was used as the substrate for the deposition of various composition of metal catalyst thin films. The disclosed compositions of the catalysts are based on the substitution of PtRu by a wide range of compositions from transition metals such as Co, Ni, V, Mn, and Cu and refractive metals such as W, Mo, Ta, and Nb. The catalytic efficiency is enhanced more than 200% in the present invention of ternary and quaternary catalysts systems based on Pt—Ru—W-M where M is Co, V, Mn, and Cu.

The present invention relates to the development of a metal catalyst based on platinum (Pt)-ruthenium (Ru) for a anode catalyst of direct methanol fuel cell (DMFC), which is an essential material for determining the performance of a DMFC. More particularly, the present invention relates to a quaternary metallic anode catalyst for a DMFC, consisting of platinum (Pt), ruthenium (Ru), and at least one of two other metals M′ and M″, the M′ and M″ being selected among transition metals from Groups V-XI of the Periodic Table of the Elements.

In one embodiment, a quaternary metal catalyst for a fuel cell comprises platinum (Pt), ruthenium (Ru), a metal M′ where M″ is selected from the group consisting of tungsten (W), molybilium (Mo), niobium (Nb) and tantalum (Ta), and a transition metal M″ where M″ is selected from the group consisting of vanadium (V), cobalt (Co), nickel (Ni), copper (Cu), and manganese (Mn).

A general formula of this ternary and/or quaternary metal system is (Pt₁₋ₓRuₓ)_{y}M′_{z}M″_{1-y-z}, where x ranges from about 0 to about 1, and y ranges from about 0.01 to about 0.99; y+z is equal to about 1; M′ is selected from the group consisting of W, Mo, Nb, and Ta; and M″ is selected from the group consisting of V, Co, Ni, Mn, and Cu.

In another embodiment, a novel fuel cell catalyst comprises new series of thin-film metal alloy catalysts with low platinum and ruthenium concentrations, the catalyst(s) supported on nanostructured materials such as nanoparticles. In certain embodiments, the integrated gas-diffusion/electrode/catalysts layer can be prepared by processing catalyst thin films and nanoparticles into gas-diffusion media such as Toray or SGL carbon fiber papers, carbon fiber cloths, porous electrodes, and the like. The catalysts may be placed in contact with an electrolyte membrane for DMFC fuel cell applications. The migration of protons through the integrated catalyst-electrode layers can be facilitated by coating the catalyst layer on nanoparticles with an ionic polymer. The layered structures of CNT catalysts, CNT, and PtRu, PtRuM′ or PtRuM′M″ alloys can be efficiently processed with high throughput using vapor deposition systems.

One of the present embodiments of this invention provides a composition comprising a plurality of conductive fibers, including but not limited to carbon fibers, metal fibers, porous electrodes, and the like, bearing nanoparticles of the form including but not limited to nanotubes, nanofibers, nanohorns, nanopowders, nanospheres, and quantum dots. In certain embodiments, the conductive fibers are not themselves nanoparticles or nanofibers. The plurality of fibers may comprise a porous electrode and/or a carbon paper, carbon cloth, carbon impregnated polymer, porous conductive polymer, a porous metal conductor, and the like. In certain embodiments, the nanoparticles comprise carbon nanotubes and the nanotubes are seeded with one or more nanotube growth catalysts having the general formula described by this ternary and/or quaternary metal system: (Pt₁₋ₓRuₓ)_{y}M′_{z}M″_{1-y-z}, where the values of x, y, and z are defined above.

Certain preferred nanotube growth catalysts include, but are not limited to Pt—Ru—W—V (40:27:15:18 or 42:28:12:18), Pt—Ru—W—Co (39:25:15:21), Pt—Ru—W—Cu (39:26:15:20), Pt—Ru—W—Mn (39:26:15:20), and Pt—Ru—W—Ni (39:25:15:21), where the numbers in parentheses are the atomic percentages of the component elements.

In various embodiments, the nanoparticles are nanotubes have a length less than about 500 μm and/or a width/diameter less than about 100 nm. In some embodiments, the width/diameter is less than about 50 nm. The nanoparticles are typically coated with a substantially continuous thin film, preferably a catalytically active thin film, e.g., a film comprising platinum or a platinum-ruthenium alloy. The thin film can partially or completely cover the nanoparticles and, in certain embodiments, ranges in thickness from about 1 to about 1000 angstroms, more typically from about 5 to about 500 angstroms. The thickness may also range from about 5 to about 100 angstroms.

### BRIEF DESCRIPTION OF THE DRAWINGS

The above objects and advantages of the present invention will become more apparent by describing in detail preferred embodiments thereof with reference to the attached drawings in which:

FIG. 1 is a schematic diagram of a Model K0264 Micro-Cell from Princeton Applied Research;

FIG. 2 shows a schematic diagram of a catalyst deposited on carbon nanotubes (CNT);

FIG. 3a is a composition library design of (Pt(10 nm)Ru(6 nm)W(4 nm)M(x), where x is the thickness gradient changing from 0 to 4 nm for M, where M is Co, Cu, Mn, and Ni;

FIG. 3b contains data measured on selected spots (0.48 cm²) for catalytic current (mA) at 0.35V vs. Ag/AgCl, 5 min. 50° C.;

FIG. 4a is a composition library design of (Pt(10 nm)Ru(6 nm)W(0-4 nm)V(0-4 nm) where the thickness gradient changes from 0 to 4 nm for W along one axis, and for V along a perpendicular axis;

FIG. 4b is a data measured on selected spots (0.48 cm²) for catalytic current (mA) at 0.35V vs. Ag/AgCl, 5 min. 50° C.;

FIG. 5a is a data plot illustrating the cyclic voltammogram for a Pt—Ru—W—V catalyst with composition (40:27:15:18) of an exemplary fuel cell equivalent electrochemical cell; according to the present invention;

FIG. 5b is a data plot illustrating the cyclic voltammogram for a Pt—Ru—W—V catalyst with composition (42:28:12:18) of an exemplary fuel cell equivalent electrochemical cell; according to the present invention;

FIG. 6 is a data plot illustrating a comparison of cyclic voltammograms for two Pt—Ru—W—V compositions and a conventnoal Pt—Ru binary catalyst in an exemplary fuel cell equivalent electrochemical cell;

FIG. 7 is a data plot illustrating a comparison of cyclic voltammograms for Pt—Ru—W—V, Co, Cu, Mn, Ni and Pt—Ru catalyst of an exemplary fuel cell equivalent electrochemical cell;

FIG. 8 is a data plot illustrating the time dependent performance of exemplary catalysts of the present embodiments at 0.35 V; and

FIG. 9 shows scanning electron microscope (SEM) images of deposited quaternary metal catalyst(s) deposited on carbon nanotubes according to the present embodiments.

### DETAILED DESCRIPTION OF THE INVENTION

In the anode of a DMFC, methanol oxidation occurs to produce protons and electrons. The produced protons and electrons are transferred to the cathode. In the cathode, the protons react with oxygen, where the reduction occurs. An electromotive force based on electrons traveling from anode to cathode is an electricity source of a fuel cell. The following reaction equations represent reactions occurring in the anode and cathode.

Anode (Negative Electrode):

CH₃OH+H₂O [symbol] CO₂+6H⁺+6e⁻

Cathode (Positive Electrode):

3/2O₂+6H⁺+6e [symbol] 3H₂O

The overall performance of a fuel cell is greatly limited by the performance of the anode catalyst(s) because the anode reaction rate is slower than the reaction that occurs at the cathode. Thus, in order to enhance the DMFC efficiency for commercial applications, development of outstanding catalyst(s) for methanol oxidation (at a current of 1 amp or higher) is quite important.

Anode materials currently being developed in the art for DMFC devices utilize predominantly a Pt—Ru binary alloy catalyst. Many of these are at least partially commercialized. Embodiments of the present invention are directed to a series of new ternary and quaternary metallic catalysts, which have proven to be highly efficient for methanol oxidation. The present ternary and quaternary metallic catalysts are contemplated to exhibit enhanced catalyst activity compared to existing catalysts. The phase equilibrium, atomic bonding strength and degree of catalyst activity are vital parameters in selecting elements and determining combination ratios of such elements. In the present investigation, a comprehensive search of different combinations of PtRu with varying transition metals was carried out by high throughput thin film depositions on CNT GDS substrates. Cyclic voltammetry (CV) tests were performed to identify the compositions having enhanced catalytic efficiency in comparison with a reference composition of a prior art PtRu composition.

According to one embodiment of the present invention, the testing method for evaluating an anode catalyst comprised generating cyclic voltammetry (CV) curves by scanning voltage from a low value of the voltage, generally about −0.13 volts, versus a reference (such Ag/AgCl in NaCl), to a high value of the voltage, 0.6 volts.

During the measurements of the CV curve, a working electrode function as the anode, and a reference electrode and counter electrode may comprise the cathode.

For comparison of activities to methanol oxidation, onset voltages of the methanol oxidation of the presently invented catalysts in a three-electrode cell from Princeton Applied Research were tested using a Pt wire as a counter electrode, and Ag/AgCl in 0.5 M sulfuric acid solution and 1M methanol/0.5 M sulfuric acid solution at 50° C. as reference electrodes were measured. Even if the same metals had been used in the synthesis of a catalyst composition, different activities to methanol oxidation were exhibited depending on the composition of the particular metals that were chosen.

Following that, changes in current were measured for 5-60 minutes by applying a constant voltage of 0.35 volts versus a Ag/AgCl solution in 1 M methanol/0.5 M sulfuric acid solution at 50° C. This test determines the stability of the synthesized catalysts under the applied voltage condition.

For a catalyst to exhibit a targeted performance, it is desirable to have a low onset voltage with respect to a methanol oxidation reaction while maintaining a constant normalized current density from the point of view of activity and stability.

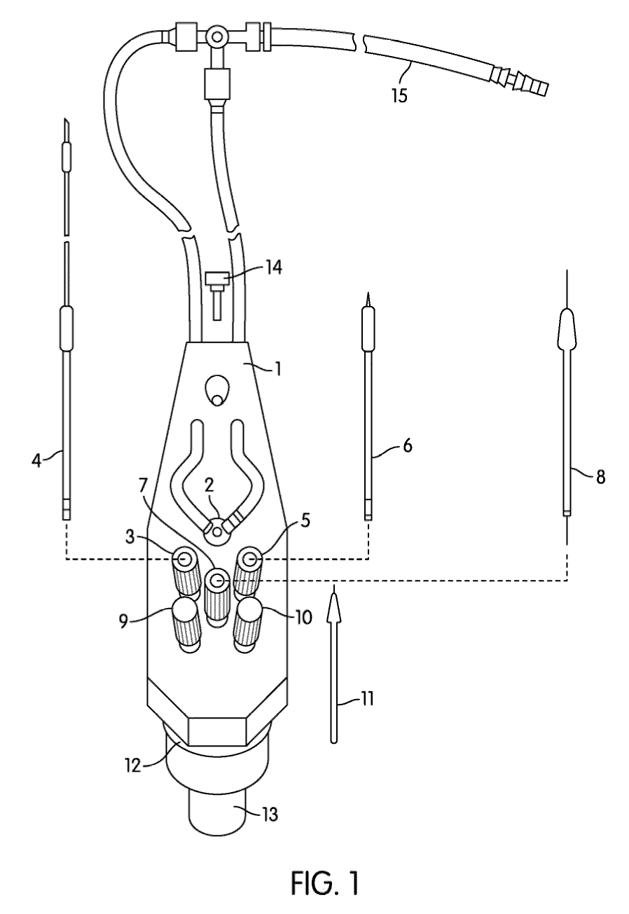

FIG. 1 is a schematic diagram of a Princeton Applied Research Micro-Cell, Model K0264, which provides an expedient way to perform electrochemical measurements in solution volumes as low as 200 μl. It is ideal for studies where only limited quantities of samples are available.

The Micro-Cell used in the following examples comes as a complete kit to which one need only add the working electrode of the experimenter's choice. The kit includes a ring-stand mountable cell top which accommodates a variety of micro or macro electrodes, a low-volume cell bottom with closure, a silver-silver chloride reference electrode, a platinum counter electrode incorporating a Vycor-fritted junction tube, and a gas purging system.

The cell top ports are fitted with electrode and auxiliary mountings which provide an effective seal against oxygen intrusion. Additional ports are provided for introduction of test solutions and temperature measurement probes. The cell top is tightly sealed to the bottom via a unique threaded closure which allows fast disassembly and expedites filling and cleaning procedures.

The reference numerals identifying components 1-15 of FIG. 1 are as follows: 1 is the cell top, made of, for example, polypropylene; 2 is the purge tube assembly, also made of polypropylene; 3 is a polypropylene bushing; 4 is a reference electrode comprising soda lime glass; 5 is a bushing made of polypropylene; 6 is a counter electrode, also made of soda lime glass; 7 is a polypropylene bushing; 8 is a working electrode comprising a micro-gold wire; 9 and 10 are polypropylene plugs; 11 is a stainless steel thermometer; 12 is a polypropylene cap; 13 is a glass specimen cell; 14 is a thermoplastic knob and 15 is polyethylene tubing.

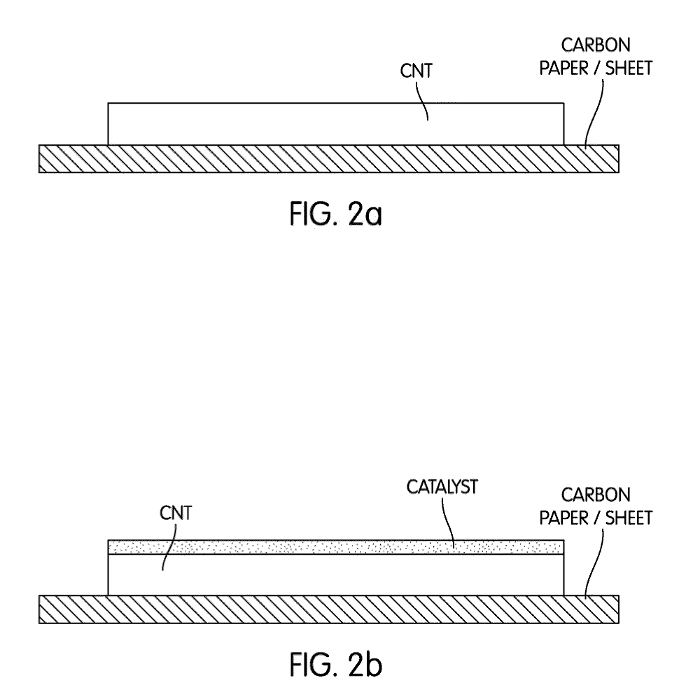

FIGS. 2A and 2B are schematic diagrams showing the process of depositing a catalyst composition on a carbon nanotube (CNT) layer itself positioned on a carbon paper or sheet. Methods of depositing the catalyst compositions include ion beam deposition using a multi-target system.

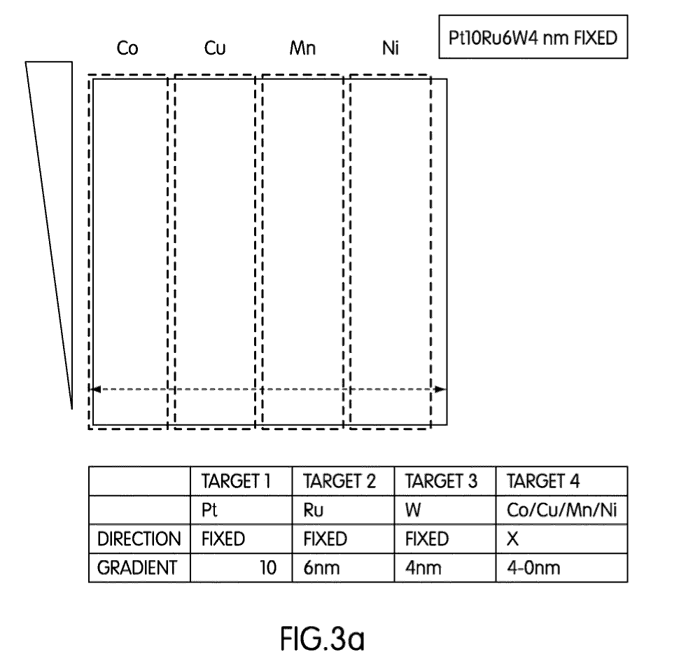

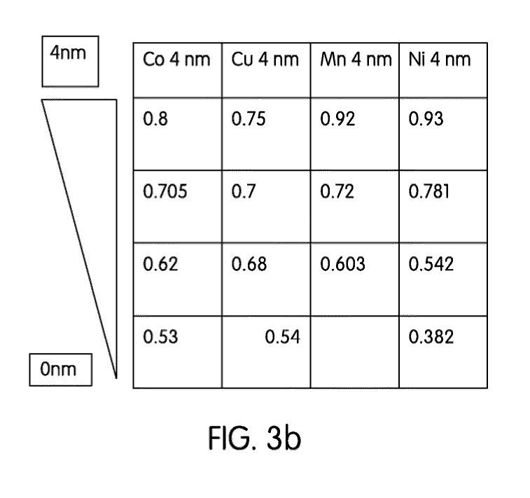

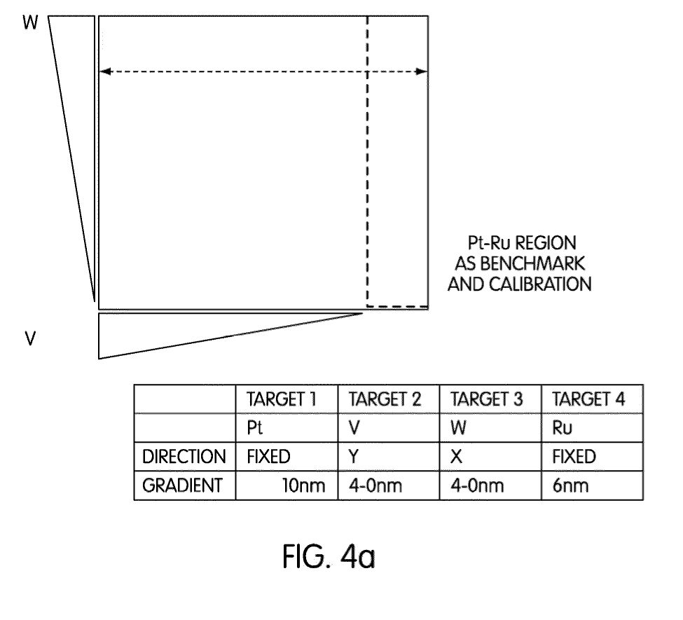

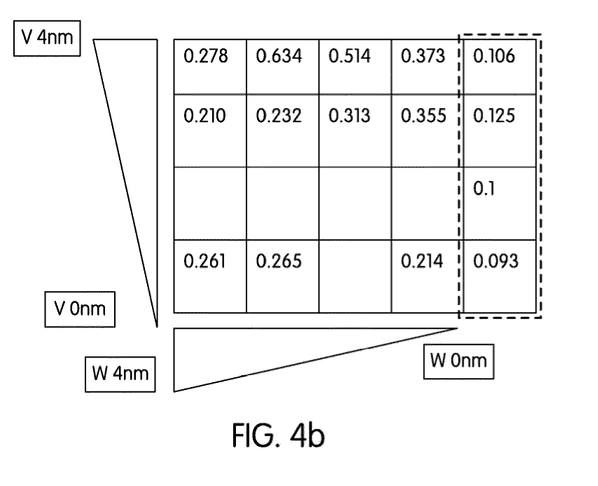

This type of deposition system allows for a large degree of flexibility in creating combinatorial libraries of various contents of either three or four metals in a catalyst system. In one embodiment, the catalyst system is a quaternary system, as illustrated schematically in FIGS. 3 and 4. FIG. 3a is a composition library design of a system whereby 10 nm of a platinum layer, 6 nm of a ruthenium layer, and 4 nm of a tungsten layer were used as a fixed system, on which a gradient of a metal M was deposited from 0 to 4 nm along one axis of the library. In this case, the metal M was one of four metals: Co, Cu, Mn, and Ni in four different linear regions. The parameter “x” represents the thickness of the metal M. Thus, electrical measurements may be taken on four different quaternary systems: 1) Pt(10 nm)Ru(6 nm)W(4 nm)Co(in a gradient along one axis of 0 to 4 nm); 2) Pt(10 nm)Ru(6 nm)W(4 nm)Cu(in a gradient of 0 to 4 nm); 3) Pt(10 nm)Ru(6 nm)W(4 nm)Mn(in a gradient of 0 to 4 nm); and 4) Pt(10 nm)Ru(6 nm)W(4 nm)Ni(in a gradient of 0 to 4 nm).

The multilayer deposition of a quaternary metal catalyst system with a gradient of selected transition metals is conducted by a ion-beam sputtering system designed for synthesis of combinatorial material libraries. Post annealing for interdiffusion of the multilayers may, according to one embodiment, be carried out at about 500° C. for about 12-24 hours.

Measurements of catalytic current (mA) at 0.35V versus a reference electrode of Ag/AgCl, taken over 5 minutes at 50° C., may be collected on selected spot sizes of, for example, 0.48 cm² on the library depicted in FIG. 3a. The catalytic efficiency compared for the electrical current at the fixed voltage of 0.35V is shown in FIG. 3b. All of the fourth additional elements on the PtRuW system enhanced the catalytic efficiency.

Combinatorial libraries may be fabricated whereby two of the four elements of a quaternary composition are varied simultaneously. FIG. 4a shows just such an arrangement, wherein W is varied from 0 to 4 nm along one axis, and V is varied along a perpendicular axis, which when looking down at the library in a plan view, appears two-dimensional. Referring to FIG. 4a, the tungsten thickness increases from 0 to 4 nm going from the bottom to the top of the library, and the vanadium increases in thickness from 0 to 4 nm going from right to left. A region of Pt—Ru with no W or V is preserved in the library (far right) as a benchmark and for calibration purposes. For all regions where W and V gradients are deposited, the Pt thickness is 10 nm, and the Ru thickness 6 nm.

The catalytic efficiency was compared for the electrical current at the fixed voltage of 0.35V, and this data is shown in FIG. 4b. The data was again measured for selected spot sizes of 0.48 cm² and catalytic currents (mA) at 0.35V vs. Ag/AgCl, 5 min. 50° C. Comparison of the regions of the library containing W and/or V show that the catalytic activity was increased relative to the benchmark/calibration region containing only the Pt—Ru alloy.

The electrochemical analysis was carried out on a three-electrode cell using a Pt wire as a counter electrode, and Ag/AgCl as a reference electrode at room temperature. Measurement of the catalytic activity was carried out in 0.5 M sulfuric acid solution and 1M methanol/0.5 M sulfuric acid solution for comparison of activities with respect to methanol oxidation.

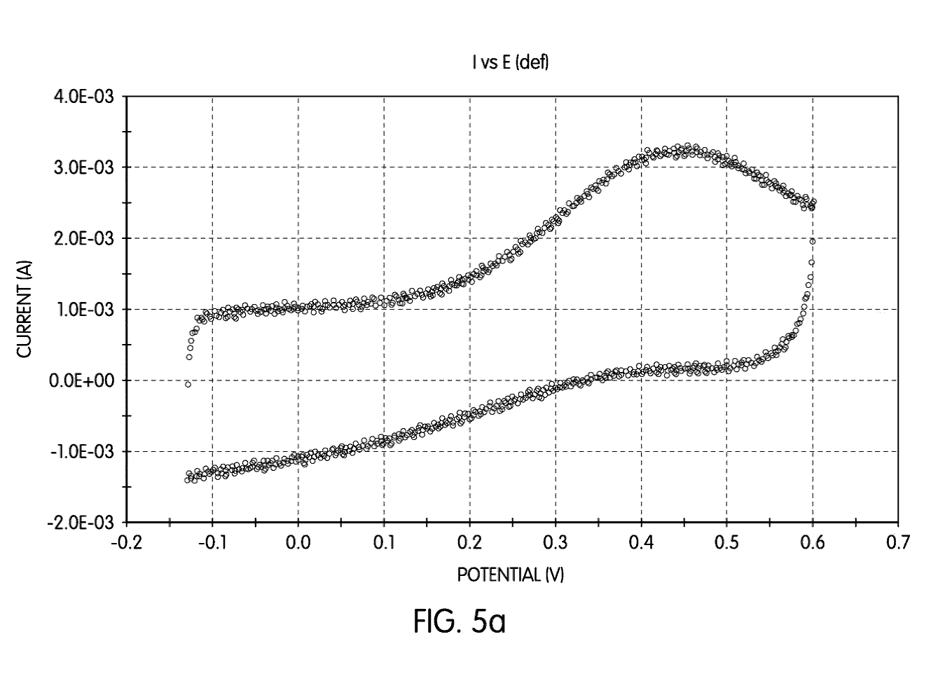

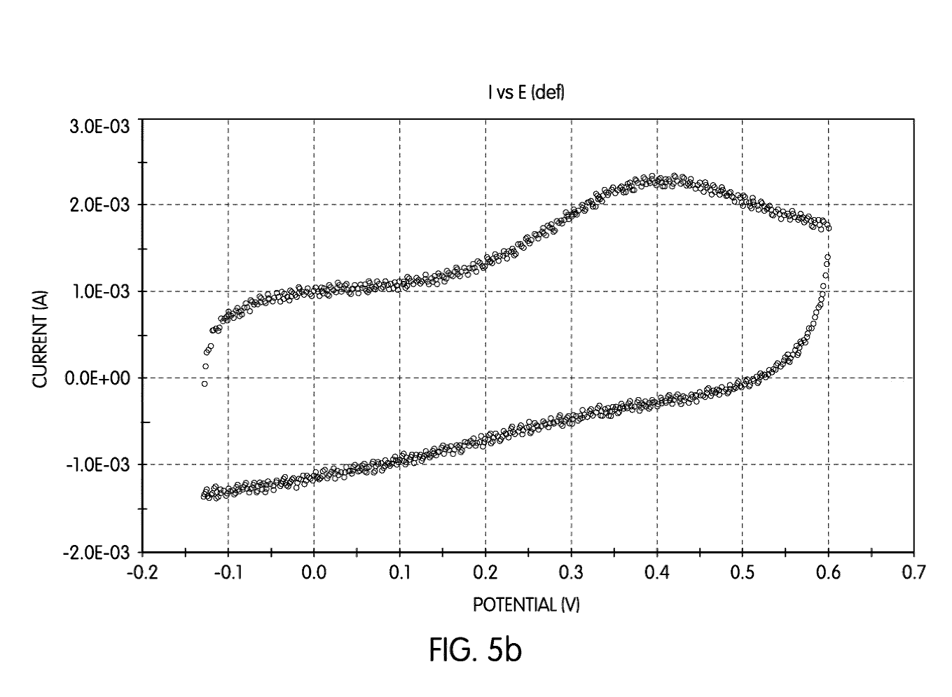

Detailed catalytic characteristics of each composition effect are shown in the cyclic voltammetry (CV) curves of FIGS. 5a and 5b. The curve in FIG. 5a is for a PtRuWV quaternary alloy having a composition 40:27:15:18 atomic percent. The cyclic voltammetry (CV) curve, again, is a scan of a voltage from a low voltage, generally negative 0.13 volts, versus a reference (Ag/AgCl in NaCl) to a high voltage, generally 0.6 volts, to evaluate anode catalysts performance. For a catalyst to exhibit excellent performance, the catalyst must meet requirements of having a low onset voltage with respect to a methanol oxidation reaction. The data of FIG. 5a shows an onset of 0.255 volts for this particular alloy composition PtRuWV (40:27:15:18).

The cyclic voltammogram of FIG. 5b is for a composition PtRuWV (42:28:12:18), this alloy shows an onset voltage of 0.275 volts.

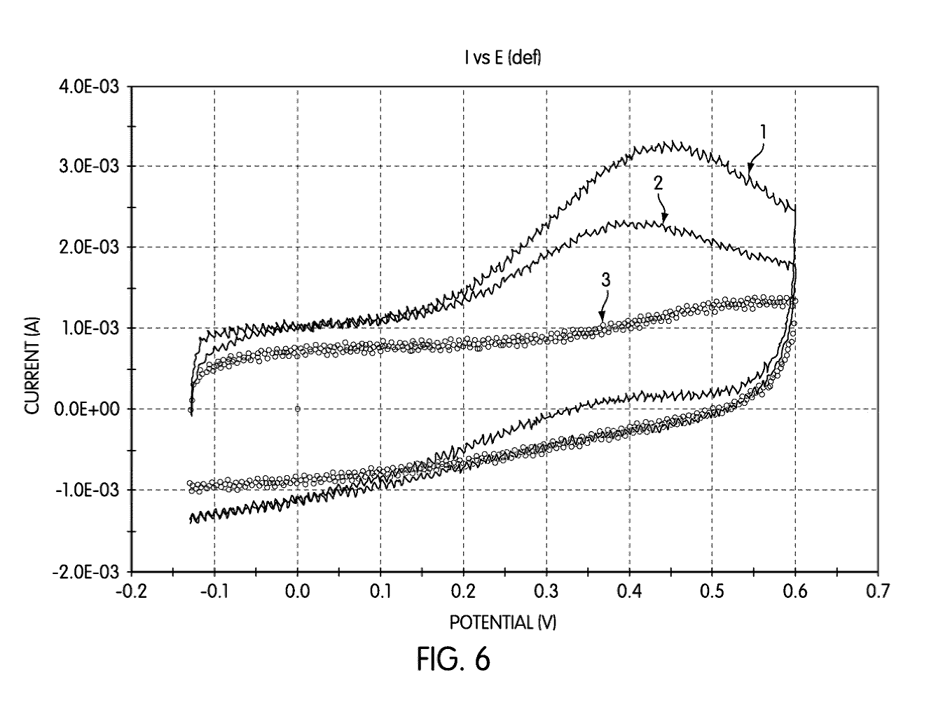

For comparison to a conventional, prior art Pt—Ru catalyst, the cyclic voltammograms of the two alloys of FIGS. 5a and 5b have been plotted against the CV curve for the conventional catalyst in FIG. 6. Referring to FIG. 6, curve 1 is the CV curve for the PtRuWV (40:27:15:18) quaternary alloy of the present invention, where again the numbers are atomic percents of the constituent metals, and curve 2 is the CV curve for the PtRuWV (42:28:12:18) quaternary alloy of the present invention. Curve 3 of FIG. 6 is the CV curve for a conventional PtRu (60:40) binary system. The onset voltages for the two exemplary quaternary compositions have been tabulated in Table 1. Table 1 shows that onset voltages of the quaternary metal catalysts compositions (a) and (b) according to the present invention are lower than the onset voltage of the conventional Pt—Ru binary catalyst as shown in FIG. 6, i.e., approximately 0.355 V, providing better catalytic activity than that in the conventional catalyst.

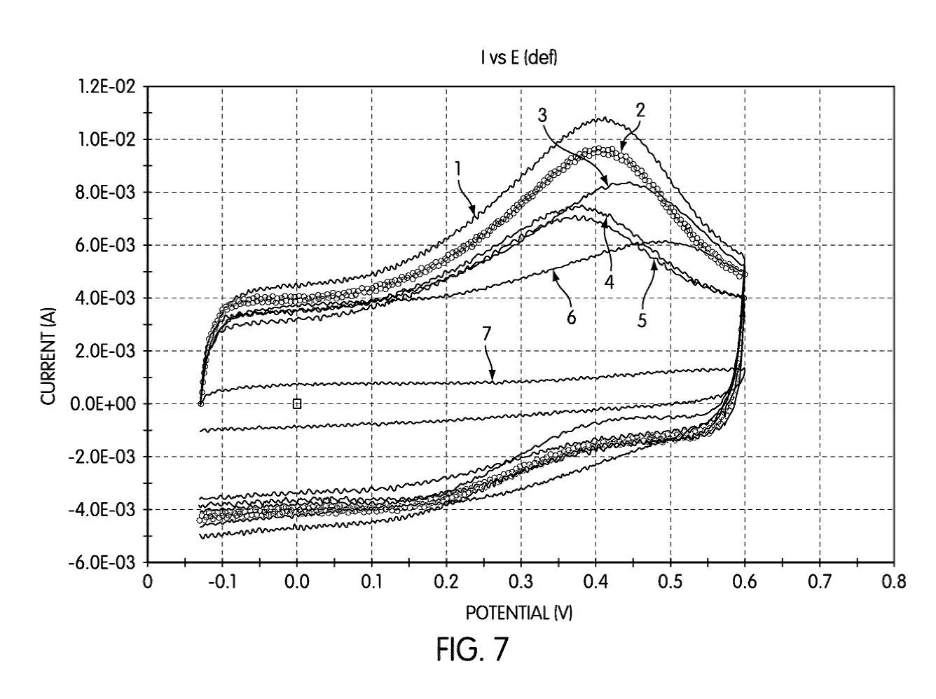

A comparison of CV curves for exemplary quaternary alloys as catalytic compositions using a Pt—Ru—W system with a fourth element selected from the group consisting of Co, Cu, Mn, and Ni is shown in FIG. 7. Referring to FIG. 7, curve 1 is a CV curve for a PtRuWMn (39:26:15:20) quaternary system; curve 2 is a CV curve for a PtRuWCo (39:25:15:21) quaternary system; curve 3 is a CV curve for the PtRuWV (40:27:15:18) quaternary system of FIG. 5a; curve 4 is a CV curve for a PtRuWMo quaternary system; curve 5 is a CV curve for the PtRuWV (40:27:15:18) quaternary system of FIG. 5b; curve 6 is a CV curve for a PtRuW (49:32:19) ternary system; and curve 7 is a CV curve for a conventional PtRu (60:40) binary system. The onset voltages for the catalysis of methanol oxidation for these alloys have been tabulated in Table 2.

In FIGS. 5 through 7, the lower the onset voltage, the better the catalyst performance. For example, the alloy having the composition Pt—Ru—W—Mn (39:26:15:20) has the lowest onset voltage (about 0.250 volts), and therefore this catalyst composition may be preferable in selected applications.

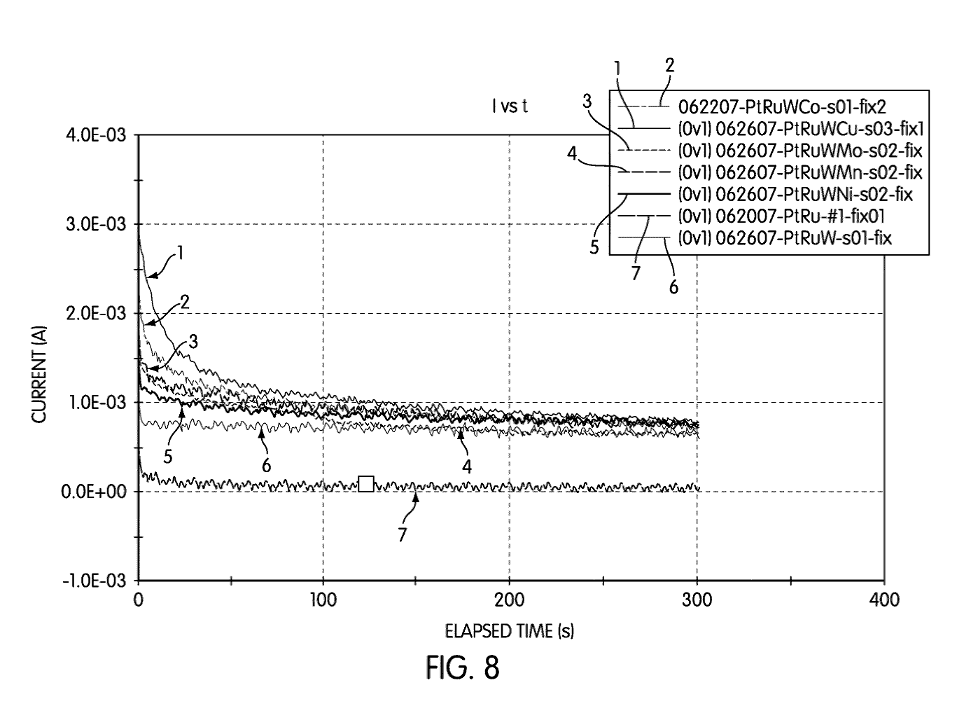

The stability of these catalyst systems may also be compared, the results showing the stability of the synthesized catalysts under the conditions where a voltage has been applied to the electrodes. FIG. 8 is a graphical comparison of changes in current (and thus, this is an electrochemical test) measured for 5 minutes while applying a constant voltage (0.35 V vs. Ag/AgCl) in 1 M methanol/0.5 M sulfuric acid solution. In FIG. 8, Pt—Ru—W/Co, Cu, Mn and Ni catalysts are mixed in atomic percents as described above and in Table 2. The higher the current shown in FIG. 8, the better the performance.

Referring to FIG. 8, curve 1 is a chronoamperometory curve for a PtRuWCu (39:26:15:20) quaternary system; curve 2 is a chronoamperometory curve for a PtRuWCo (39:25:15:21) quaternary system; curve 3 is a chronoamperometory curve for the PtRuWMn (39:26:15:20) quaternary system; curve 4 is a chronoamperometory curve for a PtRuWMo quaternary system; curve 5 is a chronoamperometory curve for the PtRuWNi (39:25:15:21) quaternary system; curve 6 is a chronoamperometory curve for a PtRuW (49:32:19) ternary system; and curve 7 is a chronoamperometory curve for a conventional PtRu (60:40) binary system.

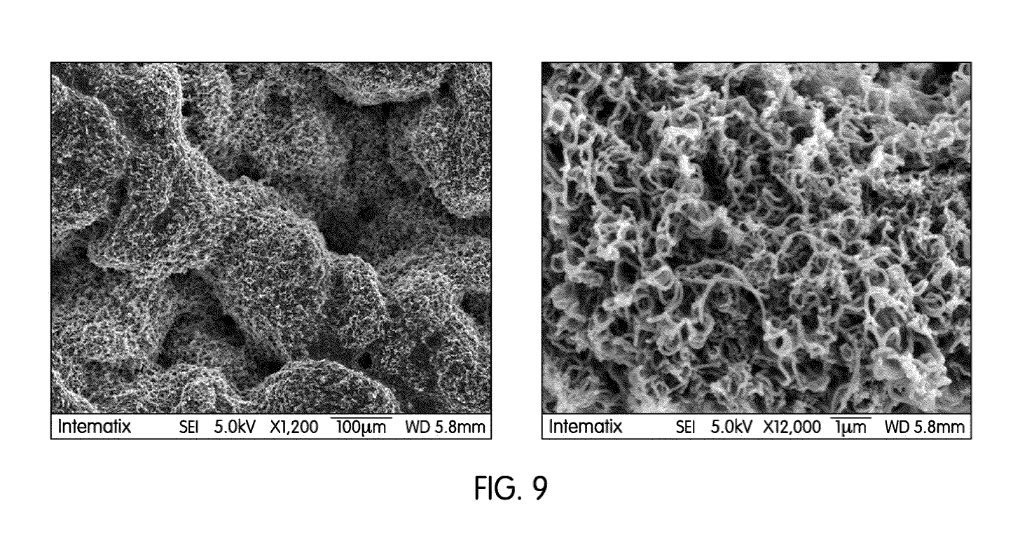

Methods of preparing the present quaternary metal catalysts include ion-beam sputtering of the catalyst component elements onto and/or into a porous carrier such as the carbon nanotubes (CNT) shown in SEM images of FIG. 9. The method for preparing the quaternary metal catalyst according to the present invention can also be applied to catalyst preparation including catalyst sputtering by ion-beam in a porous carrier such as carbon nanotubes, carbon black, activated carbon or carbon fiber.

In conclusion, compared to the conventional Pt—Ru binary metal catalyst, the Pt—Ru quaternary metal catalyst according to the present embodiments give a high power density and have advantages over conventional catalysts. The data of the present embodiments shows that even if the same metals were used in synthesizing the catalysts, different activities to methanol oxidation were exhibited according to the composition of metals used. The onset voltages of the present quaternary metal catalysts compositions are lower than the onset voltage of the conventional Pt—Ru binary catalyst, i.e., approximately 0.355 V, providing better catalytic activity than what had previously been known in the art.

TABLE 1
Onset voltage of Pt—Ru—W—V catalysts for methanol oxidation

| Atomic percent of Pt—Ru—W—V | |
|---|---|
| Pt—Ru—W—V | Onset voltage {V} |
| a) 40:27:15:18 | 0.255 |
| b) 42:28:12:18 | 0.275 |

TABLE 2
Onset voltage of Pt—Ru—W—Co, Cu, Mn, Ni
catalysts for methanol oxidation

| Atomic percent of Pt—Ru—W—Co, Cu, Mn, Ni | Onset voltage {V} |
|---|---|
| a) Pt—Ru—W—Co | 0.255 |
| 39:25:15:21 | |
| b) Pt—Ru—W—Cu | 0.265 |
| 39:26:15:20 | |
| c) Pt—Ru—W—Mn | 0.250 |
| 39:26:15:20 | |
| d) Pt—Ru—W—Ni | 0.275 |
| 39:25:15:21 | |

What is claimed is:

1. A catalyst for a direct methanol fuel cell (DMFC), the catalyst having the composition (Pt₁₋ₓRuₓ)_{y}M′_{z}M″_{1-y-z}, where
M′ is selected from the group consisting of W, Mo, Nb, and Ta;
M″ is selected from the group consisting of V, Co, Ni, Mn, and Cu;
x ranges from about 0 to about 1;
y ranges from about 0.01 to about 0.99; and
y+z is about equal to 1.

2. The catalyst of claim 1, wherein the composition is a ternary alloy.

3. The catalyst of claim 1, wherein the composition is a quaternary alloy.

4. The catalyst of claim 1, wherein the composition is Pt—Ru—W—V (40:27:15:18) atomic percent.

5. The catalyst of claim 1, wherein the composition is Pt—Ru—W—V (42:28:12:18) atomic percent.

6. The catalyst of claim 1, wherein the composition is Pt—Ru—W—Co (39:25:15:21) atomic percent.

7. The catalyst of claim 1, wherein the composition is Pt—Ru—W—Cu (39:26:15:20) atomic percent.

8. The catalyst of claim 1, wherein the composition is Pt—Ru—W—Mn (39:26:15:20) atomic percent.

9. The catalyst of claim 1, wherein the composition is Pt—Ru—W—Ni (39:25:15:21) atomic percent.

10. A method of preparing a catalyst for a direct methanol fuel cell (DMFC), the catalyst having the composition (Pt₁₋ₓRuₓ)_{y}M′_{z}M″_{1-y-z}, where
M′ is selected from the group consisting of W, Mo, Nb, and Ta;
M″ is selected from the group consisting of V, Co, Ni, Mn, and Cu;
x ranges from about 0 to about 1;
y ranges from about 0.01 to about 0.99; and
y+z is about equal to 1;
wherein the catalyst is deposited onto a porous carrier.

11. The method of claim 10, wherein the porous carrier is selected from the group consisting of a carbon nanotube, carbon black, activated carbon, and a carbon fiber.

12. The method of claim 10, where the deposition method includes ion-beam sputtering.
